(19) United States
(12) Patent Application Publication
(10) Pub. No.: US 2012/0273795 A1
(43) Pub. Date: Nov. 1, 2012

(54) SEMICONDUCTOR DEVICE

(75) Inventor: Jiang LI, Kanagawa (JP)

(73) Assignee: Advanced Power Device Research Association, Kanagawa (JP)

(21) Appl. No.: 13/455,596

(22) Filed: Apr. 25, 2012

(30) Foreign Application Priority Data
Apr. 26, 2011 (JP) 2011-098154

(51) Int. Cl. H01L 29/20

(52) U.S. Cl. 257/76; 257/E29.255; 257/E29.089

(57) ABSTRACT

Provided is a semiconductor device comprising a back barrier layer that is formed by a group III-V compound semiconductor above a substrate; a channel layer that is formed of a group III-V compound semiconductor having less bandgap energy than the back barrier layer, is formed on the back barrier layer, and includes a recessed portion formed in at least a portion of the channel layer above the back barrier layer to be thinner than other portions of the channel layer; a first electrode that is in ohmic contact with the channel layer; and a second electrode formed at least above the recessed portion of the channel layer.

### BACKGROUND

1. Technical Field

The present invention relates to a semiconductor device.

2. Related Art

A FET (Field Effect Transistor) is known that includes a substrate on which are formed an MN (aluminum nitride) layer, an AlGaN (aluminum gallium nitride) layer, a GaN (gallium nitride layer, an electron supply layer made of AlGaN, a source electrode, a drain electrode, and a gate electrode, as shown in Patent Document 1, for example. Patent Document 1: Japanese Patent Application Publication No. 2006-147663

When the electron supply layer made of AlGaN is formed on the GaN layer, 2DEG (2-dimensional electron gas) generated in the GaN layer on the AlGaN layer side near the interface between the GaN layer and the AlGaN layer causes a decrease in the ON resistance, such that Vth (threshold voltage) is less than or equal to 0 V. However, to realize a failsafe, Vth is preferably greater than 0 V. Therefore, a group III-V compound semiconductor device is desired that has low ON resistance and Vth greater than 0 V.

### SUMMARY

Therefore, it is an object of an aspect of the innovations herein to provide a semiconductor device, which is capable of overcoming the above drawbacks accompanying the related art. The above and other objects can be achieved by combinations described in the independent claims. The dependent claims define further advantageous and exemplary combinations of the innovations herein. According to a first aspect related to the innovations herein, provided is a semiconductor device including a back bather layer that is formed by a group III-V compound semiconductor above a substrate; a channel layer that is formed of a group III-V compound semiconductor having less bandgap energy than the back bather layer, is formed on the back bather layer, and includes a recessed portion formed in at least a portion of the channel layer above the back bather layer to be thinner than other portions of the channel layer; a first electrode that is in ohmic contact with the channel layer; and a second electrode formed at least above the recessed portion of the channel layer.

The summary clause does not necessarily describe all necessary features of the embodiments of the present invention. The present invention may also be a sub-combination of the features described above.

### BRIEF DESCRIPTION OF THE DRAWINGS

FIG. 1 is a schematic cross-sectional view of a FET according to a first embodiment of the present invention.

FIG. 2 shows transfer characteristics of the FET according to the first embodiment.

FIG. 3 shows a relationship between the Al composition ratio, the carrier concentration, and Vth in the FET according to the first embodiment.

FIG. 4 shows a relationship between the carrier concentration and Vth in the FET according to the first embodiment.

FIG. 5 shows a band configuration of the FET according to the first embodiment.

FIG. 6 is a schematic cross-sectional view of a FET according to a second embodiment of the present invention.

FIG. 7 is a schematic cross-sectional view of a FET according to a third embodiment of the present invention.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

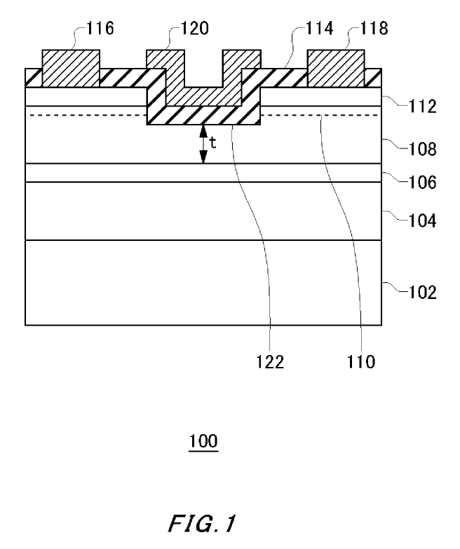

FIG. 1 is a schematic cross-sectional view of a FET 100 according to a first embodiment of the present invention. The FET 100 includes a substrate 102, a buffer layer 104, a back barrier layer 106, a channel layer 108, an electron supply layer 112, an insulating film 114, a source electrode 116, a drain electrode 118, and a gate electrode 120.

The back barrier layer 106 is formed above the substrate 102. The channel layer 108 is formed on the back barrier layer 106. The channel layer 108 is formed by a group III-V compound semiconductor having lower bandgap energy than the back barrier layer 106. A recessed portion 122 reaching the channel layer 108 is disposed above at least a portion of the back barrier layer 106. The channel layer 108 is thinner at the recessed portion 122 than at other portions. In other words, the thickness (t) of the channel layer 108 at the recessed portion 122 is less than the thickness of other portions of the channel layer 108.

The back barrier layer 106 is made of a group III-V compound semiconductor having greater bandgap energy than the channel layer 108. The crystal of the back barrier layer 106 and the crystal of the channel layer 108 have different lattice intervals, and therefore crystal structures of the back barrier layer 106 and the channel layer 108 are strained. Strain of the back barrier layer 106 causes a negative polarized charge in the back barrier layer 106 near an interface between the back barrier layer 106 and the channel layer 108. The negative polarized charge occurring in the back barrier layer 106 causes depletion on the back barrier layer 106 side of the channel layer 108.

Since the recessed portion 122 of the channel layer 108 is thinner than other portions of the channel layer 108, the recessed portion 122 of the channel layer 108 is more affected by the negative polarized charge. On the other hand, the portions of the channel layer 108 other than the recessed portion 122 are thicker than the recessed portion 122 of the channel layer 108, and therefore these other portions are less affected by the negative polarized charge. As a result, the carrier concentration of the channel layer 108 is lower at the recessed portion 122 than in other portions. Accordingly, the recessed portion 122 causes Vth of the FET 100 to be greater than 0 V. In other words, the FET 100 is normally-OFF. Furthermore, since the carrier concentration of the channel layer 108 is lower at the recessed portion 122, the leakage current between the source electrode 116 and the drain electrode 118 is small, and the breakdown voltage is large.

In the portions of the channel layer 108 other than the recessed portion 122, the effect of the negative polarized charge is less than at the recessed portion 122 of the channel layer 108, and therefore the carrier concentration is higher. Since the portions of the channel layer 108 other than the recessed portion 122 have low resistance, the ON resistance between the source electrode 116 and the drain electrode 118 is low.

The back barrier layer 106 may be made from AlₓGa₁₋ₓN (0<X≦1) and the channel layer 108 may be made from GaN. The Al composition X is preferably no less than 0.05, more preferably no less than 0.1. If X is less than 0.05, the effect of forming a depletion layer in the channel layer 108 is weak.

As another example, the back barrier layer 106 may be formed by AlₒInₚGa₁₋ₒ₋ₚN (0≦o≦1, 0≦p≦1, 0<o+p≦1) and the channel layer 108 may be formed of GaN.

The back bather layer 106 may be formed by p-type GaN or p-type AlₓGa₁₋ₓN (0<X≦1), and the channel layer 108 may be formed by GaN. The back bather layer 106 may be formed by GaN doped with B (boron) or Mg (magnesium). As another example, the back barrier layer 106 may be formed by AlₓGa₁₋ₓN (0<X≦1) doped with B or Mg. If the back bather layer 106 is formed by a p-type group III-V compound semiconductor, the bandgap is widened, and therefore a depletion layer is formed in the channel layer 108.

The back bather layer 106 is formed over the entire surface of the substrate 102. As another example, the back bather layer 106 may be formed below the gate electrode 120, and need not extend continuously below the source electrode 116 and the drain electrode 118. As yet another example, the back bather layer 106 may be formed above the substrate in regions below the gate electrode 120, the source electrode 116, and the drain electrode 118, and portions of the back bather layer 106 formed below the source electrode 116 and the drain electrode 118 may be separated from the portion of the back bather layer 106 formed below the gate electrode 120. In other words, at least a portion of the back bather layer 106 may be removed between each of the regions below the source electrode 116 and the drain electrode 118 and the region below the gate electrode 120. When the regions in which the negative polarized charge is not generated due to removal of the back bather layer 106 between the source electrode 116 and the drain electrode 118, the leakage current is reduced and the breakdown voltage is increased.

The width of the back bather layer 106 may be greater than the width of the gate electrode 120. As a result, the leakage current is further reduced. Here, the widths of the back bather layer 106 and the gate electrode 120 refer to distance in a direction perpendicular to the direction in which current flows between the source electrode 116 and the drain electrode 118, as seen from above. The length of the gate electrode 120 may be greater than the length of the bottom portion of the recessed portion 122. The length of the back bather layer 106 may be less than the length of the bottom portion of the recessed portion 122. The length of the back bather layer 106, the gate electrode 120, and bottom portion of the recessed portion 122 refers to distance in a direction parallel to the direction in which the current flows between the source electrode 116 and the drain electrode 118.

The source electrode 116 and the drain electrode 118 are formed above the channel layer 108. The source electrode 116 and the drain electrode 118 are formed on the electron supply layer 112 in a region from which the insulating film 114 is removed, and are in ohmic contact with the channel layer 108. The gate electrode 120 is formed at least above the recessed portion 122, on the insulating film 114.

The electron supply layer 112 is formed on the channel layer 108. The electron supply layer 112 may include a group III-V compound semiconductor with greater bandgap energy than the channel layer 108. The electron supply layer 112 may be formed between the channel layer 108 and the source electrode 116 and between the channel layer 108 and the drain electrode 118. As an example, the electron supply layer 112 may be formed by Al_{Y}Ga_{1-Y}N (0<Y≦1). The electron supply layer 112 is formed on the channel layer 108, and a 2DEG 110 is generated in the channel layer 108 near the interface between the channel layer 108 and the electron supply layer 112. The Al_{Y}Ga_{1-Y}N is a mixed crystal of MN and GaN. The magnitude of the Al composition ratio expressed by Y may be altered to change the bandgap, the intrinsic polarity, and the piezo polarity of the electron supply layer 112. The Al composition ratio may be Y=0.25, for example. The thickness of the electron supply layer 112 may be from 20 nm to 50 nm. A layer for suppressing scattering of the carrier may be provided between the channel layer 108 and the electron supply layer 112.

The recessed portion 122 is formed passing through the electron supply layer 112 in at least a portion of the region between the source electrode 116 and the drain electrode 118, and reaches the channel layer 108. At the recessed portion 122, the electron supply layer 112 is not provided on the channel layer 108, and therefore the 2DEG 110 is not generated in the channel layer 108. At the recessed portion 122, a portion of the channel layer 108 in the thickness direction is removed. As an example, the depth of the recessed portion 122 may be greater than the thickness of the electron supply layer 112 by at least 10 nm. By removing 10 nm or more of the channel layer 108 in the thickness direction at the recessed portion 122, the carrier concentration of the channel layer 108 may be reduced at the recessed portion 122.

The insulating film 114 is formed above at least a portion of the channel layer 108. The insulating film 114 is formed on the channel layer 108 at the recessed portion 122. The insulating film 114 is formed on the electron supply layer 112 between the source electrode 116 and the drain electrode 118. The insulating film 114 is formed to cover the recessed portion 122. The insulating film 114 may be formed by SiO₂. As another example, the insulating film 114 may be formed by Si₃N₄ or Al₂O₃.

The buffer layer 104 may be formed between the substrate 102 and the back barrier layer 106. The substrate 102 may be a silicon substrate, for example. The substrate 102 may be any substrate on which GaN crystal can be grown, such as a sapphire substrate, a GaN substrate, a MgO substrate, and a ZnO substrate, for example. The buffer layer 104 improves junction strength and buffers interactions between the substrate 102 and the back barrier layer 106 and channel layer 108 due to differences in the characteristics thereof, such as lattice constant and thermal expansion coefficient.

The buffer layer 104 is formed by GaN. As another example, the buffer layer 104 may be formed by AlN (aluminum nitride) with a thickness of 50 nm on the substrate 102. On top of this AlN layer, a set of a layer of GaN with a thickness from 5 nm to 100 nm and a layer of AlN with a thickness from 1 nm to 10 nm may be repeatedly layered 3 to 20 times, thereby forming the buffer layer 104.

The following describes a method for manufacturing the FET 100 according to the first embodiment. First, the buffer layer 104 is epitaxially grown on the substrate 102. For example, the substrate 102 is placed in an MOCVD apparatus, and then TMGa (trimethylgallium) and NH₃ are introduced into the chamber of the MOCVD apparatus with respective flow rates of 58 nmol/min and 12 L/min, to epitaxially grow GaN with a thickness of 6000 nm. The growth temperature may be 1000° C., for example.

Next, the back bather layer 106 formed by AlₓGa₁₋ₓN (0<X≦1) is epitaxially grown on the buffer layer 104. The back bather layer 106 may be formed by AlGaN with a thickness of 50 nm, for example. As one example, TMAl (trimethylaluminum), TMGa, and NH₃ may be introduced at respective flow rates of 100 nmol/min, 19 nmol/min, and 12 L/min, to epitaxially grow the back barrier layer 106 made of Al_{0.25}Ga_{0.75}N at a growth temperature of 1050° C.

The channel layer 108 is formed on the back bather layer 106 by non-doped GaN, and has a thickness of 50 nm. Here, the phrase “non-doped” means that the impurities causing conduction are not intentionally added to the GaN. It should be noted that even when the channel layer 108 is formed by non-doped GaN, if the back bather layer 106 and the electron supply layer 112 are formed by AlGaN, the channel layer 108 acts as n-type GaN. The channel layer 108 may be epitaxially grown by introducing TMGa and NH3 with respective flow rates of 19 nmol/min and 12 L/min, at a growth temperature of 1050° C. and a pressure of 200 TOM

The electron supply layer 112 is formed by AlGaN on the channel layer 108. The thickness of the electron supply layer 112 may be 24 nm, for example. As one example, an electron supply layer 112 formed by Al_{0.25}Ga_{0.75}N may be epitaxially grown by introducing TMAl, TMGa, and NH₃ with respective flow rates of 100 nmol/min, 19 μmol/min, and 12 L/min at a growth temperature of 1050° C.

The recessed portion 122 may be formed using photolithography and etching. For example, a mask may be formed on the electron supply layer 112, the portion of the electron supply layer 112 in the region where the mask is not formed may be removed, and a portion of the channel layer 108 may be removed in the depth direction. The thickness of at least the portion of the channel layer 108 on the back barrier layer 106 at the recessed portion 122 may be less than or equal to 200 nm.

The insulating film 114 may be formed on the electron supply layer 112 and the channel layer 108 at the recessed portion 122, using CVD and photolithography. For example, after using CVD to form SiO₂, the SiO₂ in the region where the source electrode 116 and the drain electrode 118 are to be formed is removed using photolithography.

The source electrode 116 and the drain electrode 118 may be formed as a layer made of Ti. The source electrode 116 and the drain electrode 118 may further include a layers formed by Al on the layer of Ti. The source electrode 116 and the drain electrode 118 may be formed via sputtering or evaporation, using a liftoff technique. Next, the source electrode 116 and the drain electrode 118 may be thermally processed. The thermal processing improves the ohmic characteristics. The thermal processing may be performed for 30 minutes at 700° C.

The gate electrode 120 is formed of polysilicon doped with phosphorous, using CVD or photolithography. The gate electrode 120 is formed by a layer made of Ni and a layer made of Au formed on the Ni layer. The gate electrode 120 may be formed as a single body via sputtering or evaporation, using the liftoff technique.

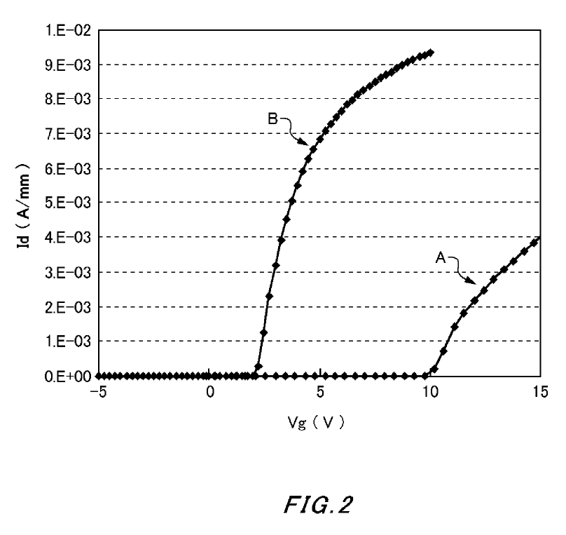

FIG. 2 shows transfer characteristics of the FET 100 according to the first embodiment. The curve A in FIG. 2 indicates the transfer characteristics of the FET 100 according to the first embodiment. The horizontal axis represents the gate voltage (V) and the vertical axis represents the drain current (A/mm) As a comparative example, the curve B indicates transfer characteristics of a FET that is identical to the FET 100 of the first embodiment, except for not including the back barrier layer 106.

In the FET 100 whose transfer characteristics are shown by the curve A in FIG. 2, the buffer layer 104 was formed of GaN with a thickness of 6000 nm, the back barrier layer 106 was formed by AlGaN with a thickness of 750 nm, the channel layer 108 was formed by non-doped GaN having a thickness of 50 nm, the electron supply layer 112 was formed by AlGaN with a thickness of 24 nm, and the insulating film 114 was formed by SiO₂ with a thickness of 60 nm. At this time, the carrier concentration of portions of the channel layer 108 other than the recessed portion 122 was 1×10¹⁶ cm⁻³.

Furthermore, in the FET 100 whose transfer characteristics are shown by the curve A in FIG. 2, the source electrode 116 and the drain electrode 118 each had a length of 10000 nm, the bottom portion of the recessed portion 122 had a length of 1000 nm, the distance between the bottom portion of the recessed portion 122 and the source electrode 116 was 3500 nm, and the distance between the bottom portion of the recessed portion 122 and the drain electrode 118 was 12000 nm. At this time, the distance from the end of the bottom portion of the recessed portion 122 on the drain electrode 118 side to the end of the gate electrode 120 on the drain electrode 118 side was 2000 nm, and therefore the gate electrode 120 included a so-called field plate with a length of 2000 nm on the drain electrode 118 side, and the distance from the end of the field plate to the drain electrode 118 was 10000 nm. The lengths of the source electrode 116, the drain electrode 118, and the field plate refer to lengths in a direction parallel to orientation of the current flowing between the source electrode 116 and the drain electrode 118. The FET 100 according to the first embodiment includes the back barrier layer 106, and therefore has a greater Vth than the FET that does not include the back barrier layer 106.

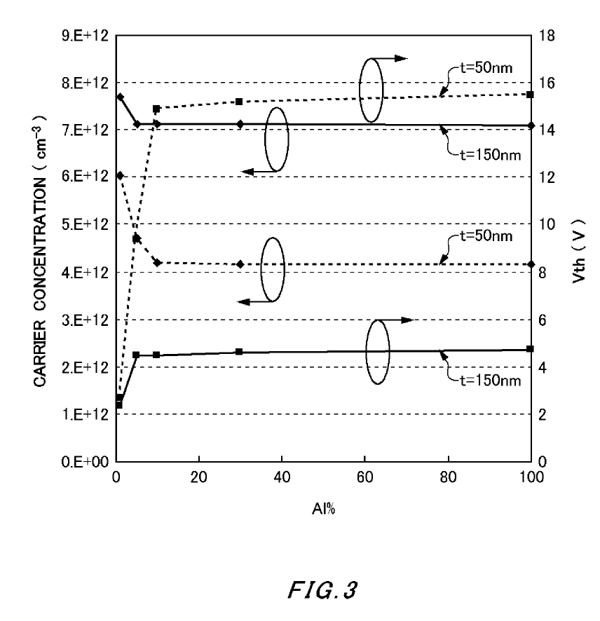

FIG. 3 shows the carrier concentration (cm⁻³)and Vth (V) at the recessed portion 122 of the FET 100 according to the first embodiment. The horizontal axis represents the Al composition ratio as a percentage of the back barrier layer 106 formed by AlₓGa₁₋ₓN (0<X≦1). The vertical axis on the left side represents the carrier concentration (cm⁻³) at the recessed portion 122. The vertical axis on the right side shows Vth (V). The dashed lines correspond to a FET 100 in which the thickness (t) of the channel layer 108 at the recessed portion 122 is 50 nm. The solid lines correspond to a FET 100 in which the thickness (t) of the channel layer 108 at the recessed portion 122 is 150 nm. When the Al composition ratio X is low, the effect of increasing Vth is also low, and therefore the Al composition ratio is preferably no less than 0.05, more preferably no less than 0.1. When X is 0.05 or greater, Vth is 4.5 V or greater.

When the thickness (t) of the channel layer 108 at the recessed portion 122 is 50 nm and X is 0.05 or greater, Vth is 9 V or greater and the carrier concentration of the channel layer 108 at the recessed portion 122 is 4×10¹² cm⁻³ or greater. When the thickness (t) of the channel layer 108 at the recessed portion 122 is 50 nm and X is 0.1 or greater, Vth is 15 V or greater and the carrier concentration of the channel layer 108 at the recessed portion 122 is 4×10¹² cm⁻³ or greater. When the thickness (t) of the channel layer 108 at the recessed portion 122 is 150 nm and X is 0.05 or greater, Vth is 4.5 V or greater and the carrier concentration of the channel layer 108 at the recessed portion 122 is 7×10¹² cm⁻³ or greater. Accordingly, the thickness of at least the portion of the channel layer 108 at the recessed portion 122 is preferably 50 nm or greater.

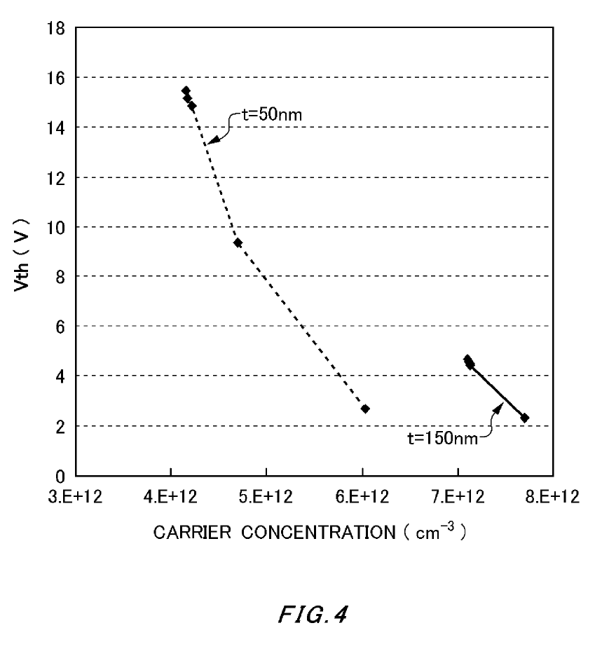

FIG. 4 is a graph in which the horizontal axis represents the carrier concentration (cm³) at the recessed portion 122 of the FET 100 according to the first embodiment and the vertical axis represents Vth (V). FIG. 4 shows Vth (V) and the carrier concentration (cm⁻³) at the recessed portion 122 of channel layers 108 with thicknesses (t) of 50 nm and 150 nm. The channel layer 108 that is thinner at the recessed portion 122 has higher Vth but lower carrier concentration.

When the channel layer 108 is thinner at the recessed portion 122, the channel layer 108 is more easily affected by the negative polarized charge generated in the back barrier layer 106 by the channel layer 108. Accordingly, the depletion of the channel layer 108 causes a high Vth and a low carrier concentration at the recessed portion 122 of the channel layer 108.

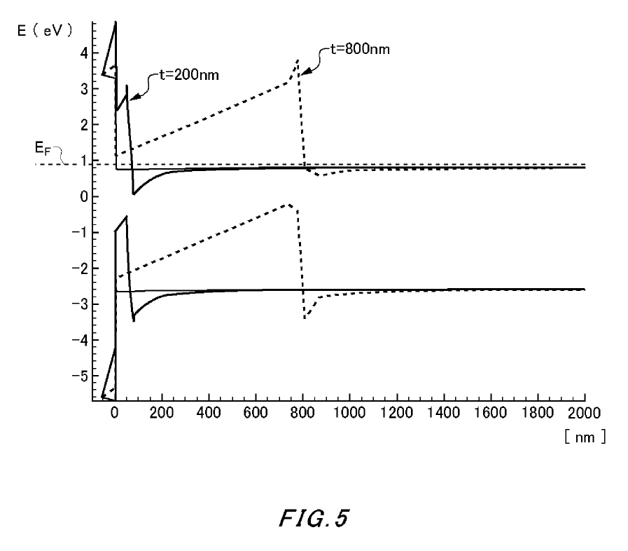

FIG. 5 shows a band configuration at the recessed portion 122 of the FET 100 according to the first embodiment. The vertical axis represents the energy level, and E_{F} represents the Fermi level. The horizontal axis corresponds to the thickness direction of the electron supply layer 112 and the channel layer 108 at the recessed portion 122. The value of 0 on the horizontal axis corresponds to the interface between the back barrier layer 106 and the channel layer 108. The solid lines and dashed lines respectively correspond to FETs 100 having channel layers 108 with thicknesses (t) of 200 nm and 800 nm at the recessed portion 122.

When the thickness of the channel layer 108 at the recessed portion 122 exceeds 800 nm, the region in which the conduction band is less than the Fermi level (E_{F}) is almost entirely eliminated, and therefore the carrier concentration at the recessed portion 122 of the channel layer 108 is low. Accordingly, the thickness of the channel layer 108 at the recessed portion 122 is preferably no greater than 800 nm. If the thickness of the channel layer 108 at the recessed portion 122 is 200 nm or less, the carrier concentration of the channel layer 108 is high and Vth is also high due to the negative polarized charge of the back barrier layer 106, and therefore a thickness of 200 nm or less is more preferable.

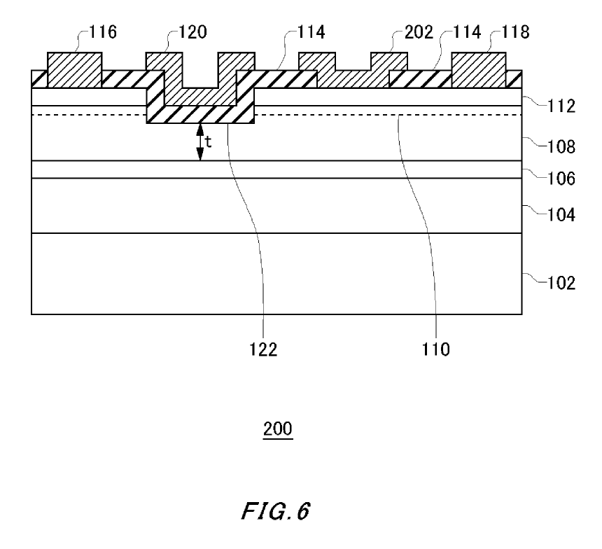

FIG. 6 is a schematic cross-sectional view of a FET 200 according to a second embodiment of the present invention. Components in FIG. 6 that have the same reference numerals as components in FIG. 1 may have the same function and configuration as these components described in FIG. 1. The FET 200 includes a substrate 102, a buffer layer 104, a back barrier layer 106, a channel layer 108, an electron supply layer 112, an insulating film 114, a source electrode 116, a drain electrode 118, a gate electrode 120, and a Schottky electrode 202.

The Schottky electrode 202 is formed above the channel layer 108 and between the gate electrode 120 and the drain electrode 118. A portion of the insulating film 114 between the gate electrode 120 and the drain electrode 118 is removed, and the Schottky electrode 202 is formed on the electron supply layer 112. The Schottky electrode 202 forms a Schottky connection with the channel layer 108. The Schottky electrode 202 is formed by polysilicon doped with phosphorous, using CVD or photolithography.

A 2DEG 110 is not formed below the gate electrode 120 by the back bather layer 106 and the recessed portion 122. By setting the thickness of the channel layer 108 at the recessed portion 122 to be no greater than 800 nm, the FET 200 has high Vth and low leakage current. Accordingly, the FET 200 of the second embodiment is normally-OFF. The Schottky electrode 202 pulls out holes from the channel layer 108 between the gate electrode 120 and the drain electrode 118. Accordingly, the FET 200 of the second embodiment has a high breakdown voltage.

A portion of the insulating film 114 is removed via etching from a region above the back bather layer 106 and separated from the drain electrode 118, and the Schottky electrode 202 is formed of polysilicon doped with phosphorous using CVD and photolithography. The Schottky electrode 202 may be formed by a layer formed by Ni and a layer formed by Au on the Ni layer. The gate electrode 120 formed by Ni/Au may be formed via sputtering or evaporation, using the liftoff technique.

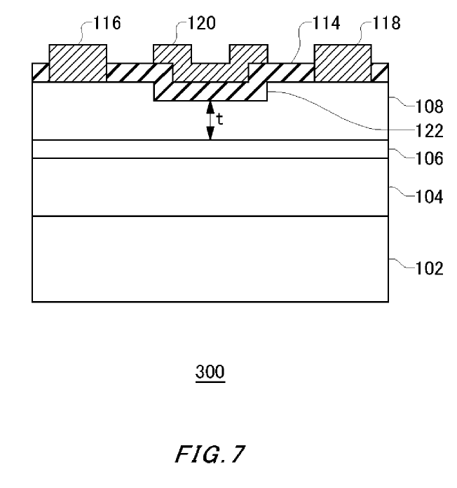

FIG. 7 is a schematic cross-sectional view of a FET 300 according to a third embodiment of the present invention. Components in FIG. 7 that have the same reference numerals as components in FIG. 1 may have the same function and configuration as these components described in FIG. 1. The FET 300 includes a substrate 102, a buffer layer 104, a back bather layer 106, a channel layer 108, an insulating film 114, a source electrode 116, a drain electrode 118, and a gate electrode 120.

The channel layer 108 is depleted by the back bather layer 106, and the channel layer 108 has low carrier concentration at the recessed portion 122. By setting the thickness (t) of the channel layer 108 at the recessed portion 122 to be 800 nm or less, the FET 300 has high Vth, high breakdown voltage, and low leakage current between the drain electrode 118 and the source electrode 116 in the OFF state.

After the channel layer 108 is formed, the recessed portion 122 is formed using photolithography and etching. Next, the insulating film 114 is formed on the channel layer 108. A portion of the insulating film 114 is removed, and the source electrode 116 and drain electrode 118 are formed on the channel layer 108. The source electrode 116 and the drain electrode 118 are each formed by a layer of Ti and a layer of Al formed on the Ti layer. The source electrode 116 and the drain electrode 118 are formed via sputtering or evaporation, using the liftoff technique. Next, the source electrode 116 and the drain electrode 118 may be thermally processed. The thermal processing improves the ohmic characteristics. The thermal processing may be performed for 30 minutes at 700° C.

The gate electrode 120 is formed on the insulating film 114. The gate electrode 120 may be formed by polysilicon doped with phosphorous, using CVD and photolithography. The gate electrode 120 may be formed by a layer of Ni and a layer of Au formed on the Ni layer. The gate electrode 120 may be formed via sputtering or evaporation, using the liftoff technique.

The channel layer 108 may include contact regions in the regions where the source electrode 116 and the drain electrode 118 are to be formed. In the contact regions, the carrier concentration may be higher than in other portions of the channel layer 108. For example, the contact regions may be formed by performing ion implantation, using silicon (Si) as the impurity, in the channel layer 108. This ion implantation may be performed after a mask having openings at the regions where the contact regions are to be formed is formed on the channel layer 108 using photolithography.

The above describes embodiments of the present invention, but the present invention is not limited to the above embodiment. For example, it is clear to someone skilled in the art that the present invention can be applied to a MIS (Metal Insulator Semiconductor) or a GIT (Gate Injection Transistor). It is also clear that the present invention can be applied to GaAs (gallium arsenic), which is a group III-V compound semiconductor. For example, the back bather layer 106 may be formed by AlₖGa₁₋ₖAs (0<k≦1), the channel layer 108 may be formed by GaAs, and the electron supply layer 112 may be formed by AlₘGa₁₋ₘAs (0<m≦1).

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

As made clear from the above, the FET 100 according to the first embodiment, the FET 200 according to the second embodiment, and the FET 300 according to the third embodiment can be used to realize a normally-OFF semiconductor device in which Vth is greater than 0 V. Furthermore, the FET 100, the FET 200, and the FET 300 can be used to realize a semiconductor device in which the leakage current between the source electrode 116 and the drain electrode 118 is small when in the OFF state, the breakdown voltage is high, and the ON resistance is low when in the ON state.

What is claimed is:

1. A semiconductor device comprising:
a back bather layer that is formed by a group III-V compound semiconductor above a substrate;
a channel layer that is formed of a group III-V compound semiconductor having less bandgap energy than the back bather layer, is formed on the back barrier layer, and includes a recessed portion formed in at least a portion of the channel layer above the back barrier layer to be thinner than other portions of the channel layer;
a first electrode that is in ohmic contact with the channel layer; and
a second electrode formed at least above the recessed portion of the channel layer.

2. The semiconductor device according to claim 1, wherein
the back barrier layer is a layer of AlₓGa₁₋ₓN (0<X≦1), and
the channel layer is a layer of GaN.

3. The semiconductor device according to claim 1, wherein
carrier concentration of the channel layer at the recessed portion is lower than the carrier concentration at portions of the channel layer other than the recessed portion.

4. The semiconductor device according to claim 2, further comprising an insulating layer formed on the channel layer at least at the recessed portion.

5. The semiconductor device according to claim 1, wherein
the back bather layer is disposed at least in a region below the second electrode.

6. The semiconductor device according to claim 4, further comprising an electron supply layer formed by a group III-V compound semiconductor having greater bandgap energy than the channel layer, and positioned at least at a portion other than the recessed portion between the channel layer and the insulating layer.

7. The semiconductor device according to claim 6, wherein
the electron supply layer is a layer of Al_{Y}Ga_{1-Y}N (0<X≦1).

8. The semiconductor device according to claim 7, wherein
aluminum composition ratio X of the back bather layer is less than aluminum composition ratio Y of the electron supply layer.

9. The semiconductor device according to claim 1, further comprising a source electrode that is in ohmic contact with the channel layer, wherein
the first electrode is a drain electrode, and
the second electrode is a gate electrode.

10. The semiconductor device according to claim 9, further comprising a Schottky electrode that is formed above the channel layer between the second electrode and the first electrode, and that forms a Schottky connection with the channel layer.

11. The semiconductor device according to claim 1, wherein
thickness of the recessed portion of the channel layer on the back bather layer is no greater than 800 nm.

12. The semiconductor device according to claim 1, wherein thickness of the recessed portion of the channel layer on the back bather layer is no greater than 200 nm.
